(19) United States
(12) Patent Application Publication
(10) Pub. No.: US 2020/0234637 A1
(43) Pub. Date: Jul. 23, 2020

(54) DISPLAY DEVICE, DISPLAY CONTROL DEVICE AND METHOD

(71) Applicants: Chengdu BOE Optoelectronics Technology Co., Ltd., Chengdu (CN); BOE TECHNOLOGY GROUP CO., LTD., Beijing (CN)

(72) Inventors: Xuerui Gong, Beijing (CN); Chuanyan Lan, Beijing (CN); Yong Yu, Beijing (CN)

(21) Appl. No.: 16/557,266

(22) Filed: Aug. 30, 2019

(30) Foreign Application Priority Data
Jan. 23, 2019 (CN) 201910064189.3

(51) Int. Cl. G09G 3/3225; G11C 19/28

(52) U.S. Cl. CPC G09G 3/3225; G09G 2310/0286; G11C 19/28

(57) ABSTRACT

The present disclosure provides a display device, a display control device and a display control method and it relates to the field of display technology. The display control device of the present disclosure includes: a plurality of shift registers, each of the shift registers being configured to output a display control signal and duty ratios of the display control signals output by the shift registers being not exactly the same; and a gating circuit coupled to the shift registers and configured to select the display control signal outputted by one of the shift registers to be transmitted to a pixel circuit in each pulse period in response to a gating signal.

### CROSS-REFERENCE

This application is based upon and claims priority to Chinese Patent Application No. 201910064189.3, filed on Jan. 23, 2019, the entire contents thereof are incorporated herein by reference.

### TECHNICAL FIELD

The present disclosure relates to the field of display technologies, and more particularly, to a display control device, a display control method and a display device.

### BACKGROUND

With the development of optical technology and semiconductor technology, flat panel display devices represented by liquid crystal displays (LCDs) and organic light emitting diodes (OLEDs) have advantages such as thinness, low energy consumption, fast reaction speed, good color purity and high contrast ratio and thus have a leading position in the field of display.

At present, many OLED display devices have adjusted their display brightness using a dimming mode in which, durations of illumination of sub-pixels are changed to adjust the display brightness without changing an input value of a data signal voltage.

However, the problem of a conventional dimming mode is that the adjustment of brightness is not exquisite enough.

It shall be noted that contents disclosed in the foregoing are for the better understanding of the background of the present disclosure and therefore it can include contents that are not the existing technology already known to those of ordinary skill in the art.

### SUMMARY

The present disclosure is to provide a display control device, a display control method and a display device.

According to an aspect of the present disclosure, there is provided a display control device. The display control device includes a plurality of shift registers configured to output a plurality of display control signals and respective duty ratios of the display control signals. The display control device includes a gating circuit coupled to the shift registers and configured to select the display control signal outputted by one of the shift registers to be transmitted to a pixel circuit in each pulse period in response to a gating signal.

In an example arrangement of the present disclosure, the gating circuit includes a plurality of switching devices, each of which is coupled to one of the shift registers and is turned on or off under the control of the gating signal.

In an example arrangement of the present disclosure, the switching device includes a thin film transistor which has a gate electrode for receiving the gating signal.

In an example arrangement of the present disclosure, the shift registers include signal input terminals respectively and are configured to generate the display control signals having different duty ratios in response to input signals received by the signal input terminals.

In an example arrangement of the present disclosure, the shift registers include a first shift register configured to output a first display control signal having a first duty ratio, and a second shift register configured to output a second display control signal having a second duty ratio which is different from the first duty ratio.

In an example arrangement of the present disclosure, the gating circuit includes a first switching device coupled to the first shift register and configured to be turned on in response to the gating signal during a first pulse period to transmit the first display control signal to the pixel circuit. The gating circuit includes a second switching device coupled to the second shift register and configured to be turned on in response to the gating signal during a second pulse period to transmit the second display control signal to the pixel circuit.

Each of the first pulse period and the second pulse period includes one or more pulse periods, and the one or more pulse periods of the first pulse period are different from that of the second pulse period.

In an example arrangement of the present disclosure, the number of shift registers is the same as the number of the pulse periods within one frame.

According to an aspect of the present disclosure, there is provided a display control method applied to the display control device according to any one of the above. The method includes selecting, by a gating signal, the display control signal outputted by one of the shift registers to be transmitted to the pixel circuit during each pulse period of each frame.

In an example arrangement of the present disclosure, the method further includes inputting different input signals to the shift registers respectively so that the shift registers generate the display control signals of different duty ratios in response to the different input signals.

According to an aspect of the present disclosure, there is provided a display device including the display control device according to any one of the above.

It should be understood that the above general description and the following detailed description are example and explanatory only and are not intended to be restrictive of the present disclosure.

### BRIEF DESCRIPTION OF THE DRAWINGS

The accompanying drawings herein are incorporated in and constitute a part of this application, illustrate arrangements of the disclosure and together with the description serve to explain the principle of the disclosure. Obviously, the drawings in the following description are only some arrangements of the present disclosure, and those skilled in the art can also obtain other drawings based on these drawings without any creative work.

FIG. 1 is a schematic structural diagram illustrating a pixel circuit in the relevant art.

FIG. 2 is a diagram illustrating a display control signal in the relevant art.

FIG. 3 is a schematic structural diagram illustrating an arrangement of a display control device according to the present disclosure.

FIG. 4 is a schematic structural diagram illustrating an arrangement of a display control device according to the present disclosure.

FIG. 5 is a diagram illustrating a signal sequence of a display control device according to an arrangement of the present disclosure.

FIG. 6 is a diagram illustrating a signal sequence of a display control device according to an arrangement of the present disclosure.

FIG. 7 is a schematic structural diagram illustrating an arrangement of a display control device according to the present disclosure.

FIG. 8 is a diagram illustrating a signal sequence of a display control device according to an arrangement of the present disclosure.

### DETAILED DESCRIPTION

The example implementations will now be described more fully with reference to the accompanying drawings. However, the example implementations may be implemented in various forms and should not be understood as being limited to the implementations set forth herein; rather, these implementations are provided so that this disclosure will be thorough and complete, and will fully convey the concept of example implementations to those skilled in the art. In the drawings, the same reference numerals denote the same or similar structures, thus their detailed description will be omitted.

Although relative terms such as “upper” and “lower” are used in this specification to describe a relative relationship of one component to another component illustrated, these terms are used in this specification for convenience only, for example, based on a direction of an example illustrated in the accompanying drawings. It will be understood that if a device illustrated is turned upside down, the “upper” component will become the “lower” component. When one structure is “on” the other structure, which means that the structure is integrally formed on the other structure, or the structure is “directly” disposed on the other structure, or the structure is “indirectly” disposed on the other structure through another structure.

Terms “a”, “an”, “the” and “said” are used to denote the presence of one or more elements/constituent parts/etc; terms “including” and “having” represent open including and refer to the presence of additional elements/constituent parts/etc in addition to the listed elements/constituent parts/etc; terms “first”, “second” and “third” are only used for distinguishing, rather than limiting the number of objects.

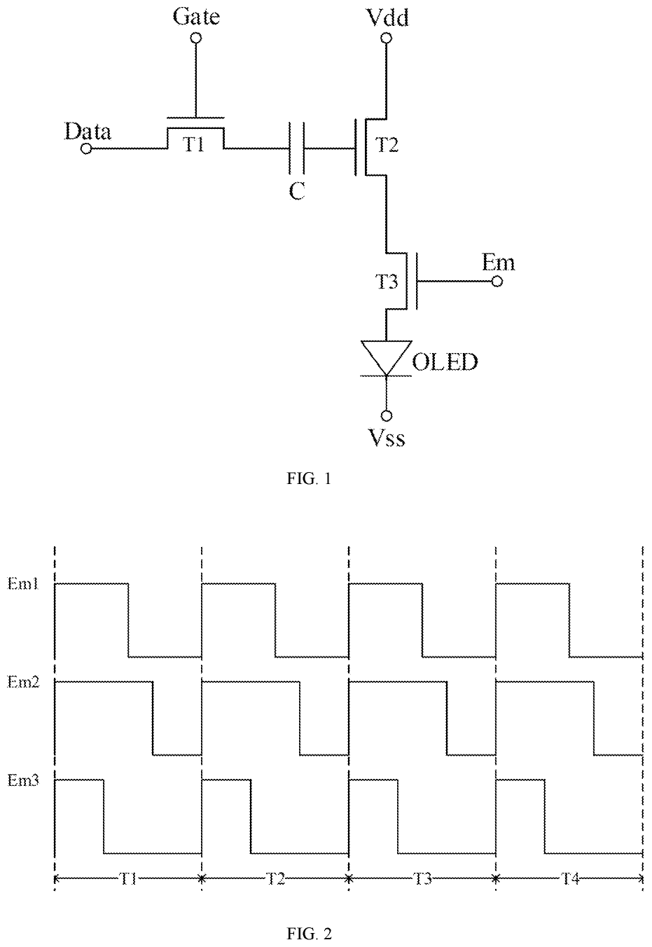

FIG. 1 shows a simple OLED pixel circuit in the relevant technology. When the pixel circuit is in operation, in a charging phase, a first switching transistor T1 may be turned on by a scan signal Gate so that a data signal Data is written into a capacitor C for charging; and in a light emitting phase, a driving transistor T2 is turned on by the signal stored in the capacitor C, and in the meanwhile, a second switching transistor T3 is turned on by a display control signal Em, so that an OLED (Organic Light Emitting Diode) emits light under the power signals Vdd and Vss.

FIG. 2 shows three display control signals Em1, Em2 and Em3 with different duty ratios. The display control signal Em2 has the largest duty ratio, the display control signal Em1 has the second largest duty ratio and the display control signal Em3 has the smallest duty ratio. The OLED emits light under the control of the display control signal Em, and thus the light emitting duration of the OLED lies on the duty ratio of the display control signal Em. Specifically, the larger the duty ratio is, the longer the light emitting duration will be. For example, in comparison to that when the display control signals Em1 and Em3 are input, when the display control signal Em2 is input, a sub-pixel in which the OLED pixel circuit shown in FIG. 1 is located has the longest light emitting duration.

During the display time of one frame, the light emitting duration of the sub-pixel is, to some extent, positively correlated with the display brightness thereof. Therefore, in a dimming mode of a conventional display device, the light emitting durations of respective sub-pixels are adjusted to change the display brightness without changing an input value of the data signal Data. Namely, the duty ratio of the display control signal Em may be adjusted to change the display brightness.

Referring again to FIG. 2, in each frame cycle, the display control signal has four identical pulse periods T1˜T4. In the conventional OLED display device, the display control signal Em described above is generated by a shift register; further, the duty ratio is controlled by the shift register in the relevant art. However, the problem is that a duty ratio of a single pulse period cannot be adjusted, namely, as the duty ratio of the display control signal is adjusted, all of the duty ratios of the four pulse periods should be changed identically, so the adjustment of brightness will not be exquisite enough.

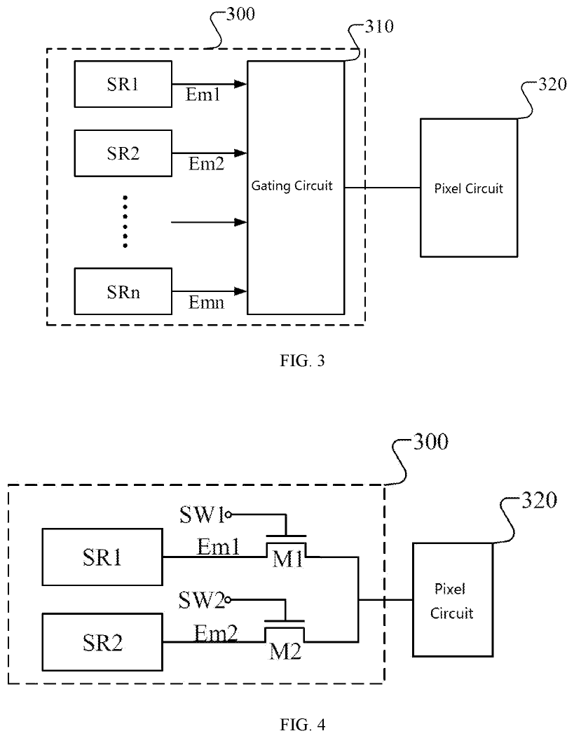

Based on the above-described contents, this example arrangement provides a display control device. Referring to FIG. 3, the display control device 300 mainly includes a plurality of shift registers SR1˜SRn and a gating circuit 310. Each of the shift registers is configured to output a display control signal and duty ratios of the display control signals output by the shift registers SR1˜SRn are not exactly the same. The gating circuit is coupled to each of the shift registers and configured to select the display control signal outputted by one of the shift registers to be transmitted to a pixel circuit 320 in each pulse period according to a gating signal.

By way of example, the display control signal Em outputted by the shift register SR1 has the duty ratio of 1/a, the display control signal Em2 outputted by the shift register SR2 has the duty ratio of 1/b and the display control signal output by the shift register SRn has the duty ratio of 1/c. If a target display control signal includes four pulse periods, the display control signal Em2 outputted by the shift register SR2 is selected to be transmitted to the pixel circuit in the first and second pulse periods, the display control signal Em3 outputted by the shift register SR3 is selected to be transmitted to the pixel circuit in the third pulse period, and the display control signal Em4 outputted by the shift register SR4 is selected to be transmitted to the pixel circuit in the fourth pulse period. Alternatively, the display control signal Em1 outputted by the shift register SR1 is selected to be transmitted to the pixel circuit in the first pulse period, the display control signal Em2 outputted by the shift register SR2 is selected to be transmitted to the pixel circuit in the second pulse period, the display control signal Em3 outputted by the shift register SR3 is selected to be transmitted to the pixel circuit in the third pulse period, and the display control signal Em4 outputted by the shift register SR4 is selected to be transmitted to the pixel circuit in the fourth pulse period. Alternatively, the display control signal Emn outputted by the shift register SRn is selected to be transmitted to the pixel circuit in the first pulse period, the display control signal Em5 outputted by the shift register SR5 is selected to be transmitted to the pixel circuit in the second pulse period, and the display control signal Em1 outputted by the shift register SR1 is selected to be transmitted to the pixel circuit in the third and fourth pulse periods.

Herein, the duty ratios 1/a, 1/b, 1/c may be not exactly the same. According to an arrangement, the duty ratios 1/a, 1/b, 1/c may be not completely different, that is, the duty ratio of the display control signal output by any one of the shift registers is different from the duty ratios of the display control signals output by the other ones of the shift registers.

It should be noted that the shift register usually includes a signal input terminal, a signal output terminal, a pull-up unit, a pull-up control unit, a pull-down unit, a pull-down control unit and a bootstrap capacitor. The signal input terminal of the shift register is configured to receive an input signal and then generate an output signal (i.e. a display control signal.) which has the same waveform as and a different phase from those of the input signal under the action of the pull-up unit, the pull-up control unit, the pull-down unit, the pull-down control unit and the bootstrap capacitor. Therefore, in this example arrangement, input signals of different duty ratios (for example, input signals or start signals of the shift registers of the neighboring stages) may be input to the signal input terminals of different shift registers, and then the shift registers may generate the display control signals of different duty ratios according to the input signals received by the signal input terminals.

In light of the above, the precise and targeted adjustment of the display control signal received by the pixel circuit in a single pulse period may be realized by the display control device in this example arrangement. The method for the adjustment of the signal duty ratio in this example arrangement is more exquisite than the method for the same adjustment of all of the duty ratios of the pulse periods in the prior art, and then brightness of the sub-pixel in which the pixel circuit resides can be more finely adjusted to improve the quality of a display screen.

In this example arrangement, the gating circuit may include a plurality of switching devices which are switchable. For example, the gating circuit may include a plurality of switching devices, each of which is coupled to one of the shift registers and is turned on or off under the control of the gating signal. The gating signal may be accordingly a current signal or a voltage signal depending on different switching devices, which is not particularly limited in this example arrangement. In this example arrangement, the switching device may include a thin film transistor and the thin film transistor has a gate electrode which receives the gating signal and thus it may be turned on or off under the control of the gating signal. When the thin film transistor is used as the switching device, when a thin film transistor of the pixel circuit may be formed on an array substrate, the gating circuit may be formed simultaneously, which simplifies processes and reduces costs. Certainly, in other example arrangements of the present disclosure, the switching device may also be other types of controllable switches such as an insulated gate bipolar transistor, a bipolar transistor, an insulated gate field effect transistor, a thyristor, which also falls into the protection scope of the present disclosure.

In this example arrangement, only the duty ratios of part of the pulse periods of the display control signal may be separately adjusted in one frame. Alternatively, all of the duty ratios of the pulse periods of the display control signal may be separately adjusted in one frame.

By way of example, referring to FIG. 4, the shift registers may include a first shift register SR1 and a second shift register SR2. The first shift register SR1 may be used to output a first display control signal Em1 having a first duty ratio and the second shift register SR2 may be used to output a second display control signal Em2 having a second duty ratio which is different from the first duty ratio. Correspondingly, the gating circuit may include a first switching device M1 and a second switching device M2. The first switching device M1 is coupled to the first shift register SR1 and is turned on in response to a gating signal SW1 during a first pulse period to transmit the first display control signal Em1 to a pixel circuit 320. The second switching device M2 is coupled to the second shift register SR2 and is turned on in response to a gating signal SW2 during a second pulse period to transmit the second display control signal Em2 to the pixel circuit 320. Both the first pulse period and the second pulse period include one or more pulse periods but they do not include the same pulse period.

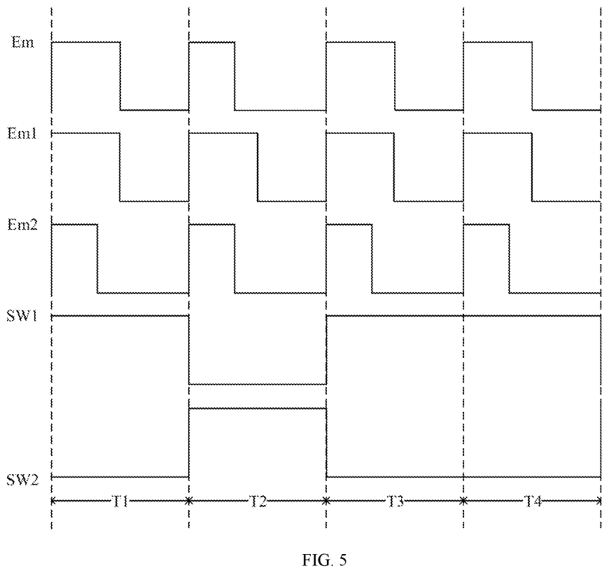

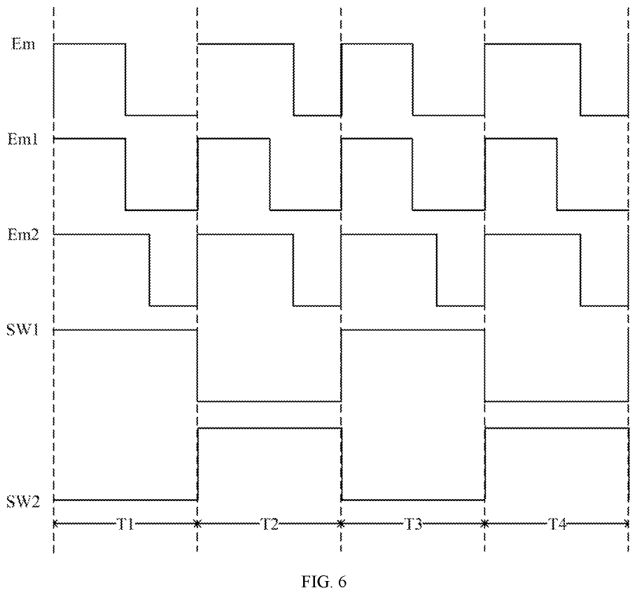

For example, as shown in FIG. 5, the display control signal Em received by the pixel circuit 320 includes four pulse periods T1 to T4. The first pulse period includes a pulse period T1, a pulse period T3 and a pulse period T4 and the signal duty ratio in the first pulse period needs to be 1/2. The second pulse period includes a pulse period T2 and the signal duty ratio in the second pulse period needs to be 1/3. Thus, the first duty ratio can be controlled to be 1/2 and the second duty ratio can be controlled to be 1/3 by the input signals of the respective shift registers. Furthermore, as shown in FIG. 5, the first switching device M1 and the second switching device M2 are controlled based on the gating signals SW1 and SW2 in such a manner that the first switching device M1 is turned on during the pulse period T1, the pulse period T3 and the pulse period T4 while the second switching device M2 is turned on during the pulse period T2. For another example, as shown in FIG. 6, the first pulse period includes the pulse period T1 and the pulse period T3 and the signal duty ratio in the first pulse period needs to be 1/2. The second pulse period includes the pulse period T2 and the pulse period T4 and the signal duty ratio in the second pulse period needs to be 2/3. Thus, the first duty ratio can be controlled to be 1/2 and the second duty ratio can be controlled to be 2/3 by the input signals of the respective shift registers. Moreover, as shown in FIG. 6, the first switching device M1 and the second switching device M2 are controlled by the gating signals SW1 and SW2 such that the first switching device M1 is turned on during the pulse period T1 and the pulse period T3 and the second switching device M2 is turned on during the pulse period T2 and the pulse period T4. Therefore, the duty ratios of part of the pulse periods of the display control signal can be individually adjusted in one frame by the display control device as shown in FIG. 4 based on the input signals of the respective shift registers.

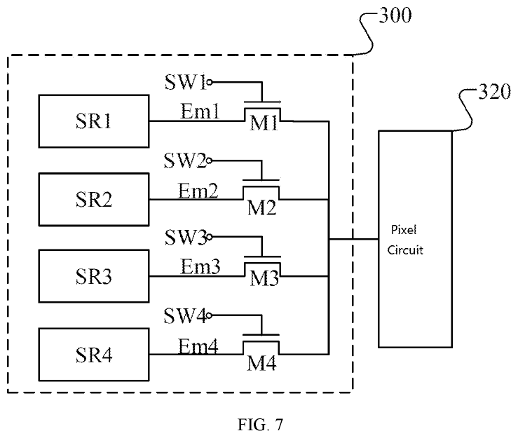

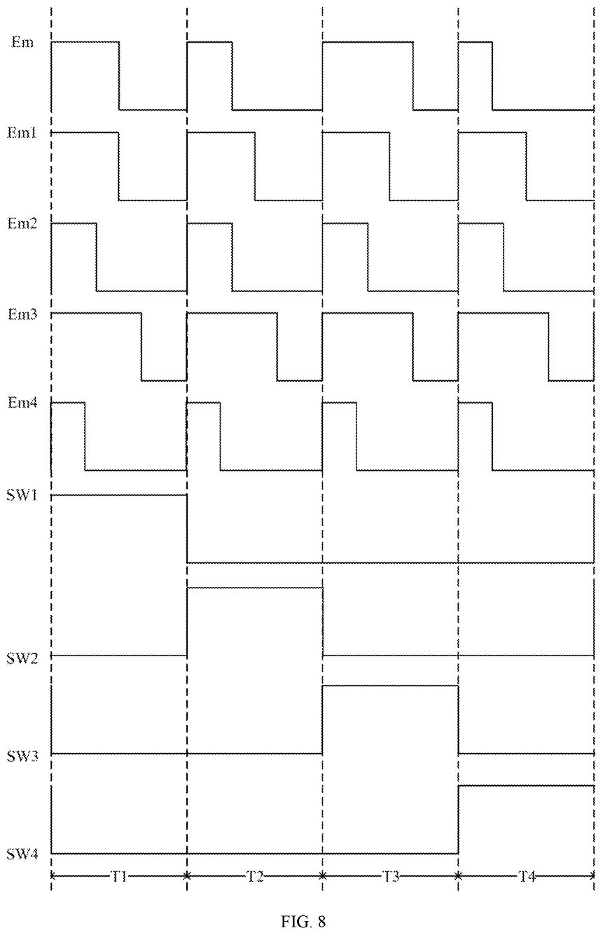

Referring to FIG. 7, the shift registers may include four shift registers (a first shift register SR1 to a fourth shift register SR4). The display control signal received by the pixel circuit 320 includes four pulses periods T1˜T4, namely, the number of the shift registers is the same as that of the pulse periods in one frame. The first to fourth shift registers SR1 to SR4 may be respectively used to output display control signals Em1 to Em4 having a first duty ratio to a fourth duty ratio. Correspondingly, the gating circuit may include first to fourth switching devices M1 to M4. For example, as shown in FIG. 8, the signal duty ratio in the pulse period T1 needs to be 1/2, the signal duty ratio in the pulse period T2 needs to be 1/3, the signal duty ratio in the pulse period T3 needs to be 2/3 and the signal duty ratio in the pulse period T4 needs to be 1/4. The input signals of the respective shift registers controls the first duty ratio to be 1/2, the second duty ratio to be 1/3, the third duty ratio to be 2/3 and the fourth duty ratio to be 1/4. Furthermore, as shown in FIG. 8, the first to fourth switching devices M1 to M4 are controlled by the gating signals SW1 to SW4 so that the first switching device M1 is turned on during the pulse period T1, the second switching device M2 is turned on during the pulse period T2, the third switching device M3 is turned on during the pulse period T3 and the fourth switching device M4 is turned on during the pulse period T4. Therefore, the duty ratios of all of the pulse periods of the display control signal can be individually adjusted in one frame by the display control device shown in FIG. 7 based on the input signals of the respective shift registers.

Certainly, in other example arrangements of the present disclosure, the number of shift registers may be greater than 2 and less than the number of the pulse periods within one frame, which is not particularly limited in this example arrangement.

Further, in an example arrangement, there is also provided a display control method applied to the above display control device. Specifically, the method may include: selecting, by a gating signal, the display control signal outputted by one of the shift registers to be transmitted to the pixel circuit during each pulse period of each frame. Furthermore, the display control method may further include inputting different input signals to the shift registers so that the shift registers generate the display control signals of different duty ratios in response to the different input signals.

An arrangement of the present disclosure also provides a display device that may include a display panel and the display control device in the above arrangements. Since the display control device of the display device is the same as that in the above arrangements, they have the same technical effects and will not be described in detail herein.

In an example arrangement, the display panel included in the display device may be an OLED display panel or a liquid crystal display panel and it may also be a quantum dot display panel or an electronic paper display panel. In terms of specific product, the display device may include, for example, any product or component having a display function, such as a mobile phone, a tablet computer, a television, a notebook computer, a digital photo frame, a navigator.

What is claimed is:

1. A display control device, comprising:
a plurality of shift registers configured to output a plurality of display control signals, and respective duty ratios of the plurality of display control signals are different; and
a gating circuit coupled to the shift registers and configured to select, according to a gating signal, one of the display control signals outputted by one of the shift registers to be transmitted to a pixel circuit in each of a plurality of pulse periods.

2. The display control device according to claim 1, wherein the gating circuit comprises a plurality of switching devices, and wherein each of the plurality of switching devices is coupled to one of the shift registers and is turned on or off based on the gating signal.

3. The display control device according to claim 2, wherein the switching devices each comprises a thin film transistor which has a gate electrode for receiving the gating signal.

4. The display control device according to claim 1, wherein the shift registers comprise signal input terminals respectively that are configured to generate the display control signals having different duty ratios in response to input signals received by the signal input terminals.

5. The display control device according to claim 1, wherein the shift registers comprise:
a first shift register configured to output a first display control signal having a first duty ratio; and
a second shift register configured to output a second display control signal having a second duty ratio which is different from the first duty ratio.

6. The display control device according to claim 5, wherein the gating circuit comprises:
a first switching device coupled to the first shift register and configured to be turned on according to the gating signal during a first pulse period to transmit the first display control signal to the pixel circuit; and
a second switching device coupled to the second shift register and configured to be turned on according to the gating signal during a second pulse period to transmit the second display control signal to the pixel circuit,
wherein each of the first pulse period and the second pulse period comprises one or more pulse periods, and the one or more pulse periods of the first pulse period are different that of the second pulse period.

7. The display control device according to claim 1, wherein a number of the shift registers is the same as a number of the pulse periods in one frame.

8. The display control method according to claim 1, wherein the duty ratio of the display control signal output by any one of the shift registers is different from the duty ratios of the display control signals output by the other ones of the shift registers.

9. A display control method applied to the display control device according to claim 1, comprising:
selecting, by the gating signal, the display control signal outputted by one of the shift registers to be transmitted to the pixel circuit during each of the pulse periods of each frame.

10. The display control method according to claim 9, further comprising:
inputting different input signals to the shift registers respectively so that the shift registers generate the display control signals having different duty ratios according to the different input signals.

11. A display device comprising a display control device, wherein the display control device comprises:
a plurality of shift registers configured to output a plurality of display control signals, and duty ratios of the plurality of the display control signals; and
a gating circuit coupled to the shift registers and configured to select, according to a gating signal, the display control signal outputted by one of the shift registers to be transmitted to a pixel circuit in each of a plurality of pulse periods.

12. The display device according to claim 11, wherein the gating circuit comprises a plurality of switching devices, and wherein each of the plurality of switching devices is coupled to one of the shift registers and is turned on or off based on the gating signal.

13. The display device according to claim 12, wherein the switching devices each comprises a thin film transistor which has a gate electrode for receiving the gating signal.

14. The display device according to claim 11, wherein the shift registers comprise signal input terminals respectively and are configured to generate the display control signals having different duty ratios in response to input signals received by the signal input terminals.

15. The display device according to claim 11, wherein the shift registers comprise:
a first shift register configured to output a first display control signal having a first duty ratio; and
a second shift register configured to output a second display control signal having a second duty ratio which is different from the first duty ratio.

16. The display device according to claim 15, wherein the gating circuit comprises:
a first switching device coupled to the first shift register and configured to be turned on according to the gating signal during a first pulse period to transmit the first display control signal to the pixel circuit; and
a second switching device coupled to the second shift register and configured to be turned on according to the gating signal during a second pulse period to transmit the second display control signal to the pixel circuit,
wherein each of the first pulse period and the second pulse period comprises one or more pulse periods, and the one or more pulse periods of the first pulse period are different that of the second pulse period.

17. The display device according to claim 11, wherein a number of the shift registers is the same as a number of the pulse periods in one frame.

18. The display device according to claim 11, wherein the duty ratio of the display control signal output by any one of the shift registers is different from the duty ratios of the display control signals output by other ones of the shift registers.
